(19) United States
(12) Patent Application Publication
(10) Pub. No.: US 2017/0004978 A1
(43) Pub. Date: Jan. 5, 2017

(54) METHODS OF FORMING HIGH DENSITY METAL WIRING FOR FINE LINE AND SPACE PACKAGING APPLICATIONS AND STRUCTURES FORMED THEREBY

(71) Applicants: Chi-won Hwang, Tsukuba (JP); Yoshihiro Tomita, Tsukuba (JP)

(72) Inventors: Chi-won Hwang, Tsukuba (JP); Yoshihiro Tomita, Tsukuba (JP)

(73) Assignee: INTEL CORPORATION, Santa Clara, CA (US)

(21) Appl. No.: 11/968,116

(22) Filed: Dec. 31, 2007

(51) Int. Cl. H01L 21/48; H05K 3/12; H05K 3/40; H01L 23/498; H05K 3/00

(52) U.S. Cl. CPC H01L 21/486; H01L 23/49822; H01L 23/49827; H01L 23/49838; H05K 3/0026; H05K 3/4053; H05K 3/1291; H05K 3/1216

(57) ABSTRACT

Methods of forming microelectronic device structures are described. Those methods may include forming at least one opening through a build up structure and a photo sensitive material disposed on the build up structure, wherein the build up structure comprises a portion of a package substrate, filling the at least one opening with a metal containing nanopaste, and sintering the metal containing nanopaste to form a bulk property metal structure in the at least one opening.

### BACKGROUND OF THE INVENTION

Microelectronic package design is moving towards increasingly finer lines to meet the demands of more functionality and higher speed. This trend has placed increasing demand on high density printed circuit boards (PCBs) and package substrates. Extending conventional packaging build up processes to meet finer line dimensions using existing wiring techniques has created a bottleneck in packaging fabrication.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1h represent structures according to an embodiment of the present invention.

FIGS. 2a-2b represent structures according to an embodiment of the present invention.

FIGS. 3a-3c represent structures according to an embodiment of the present invention.

FIGS. 4a-4c represent structures according to an embodiment of the present invention.

FIG. 5 represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods of forming microelectronic structures are described. Those methods may include may include forming at least one opening through a build up structure and a photo sensitive material disposed on the build up structure, wherein the build up structure comprises a portion of a package substrate, filling the at least one opening with a metal containing nanopaste, and sintering the metal containing nanopaste to form a bulk property metal structure in the at least one opening. Methods of the present invention enable the fabrication of fine line/space wiring for use in packaging applications, for example.

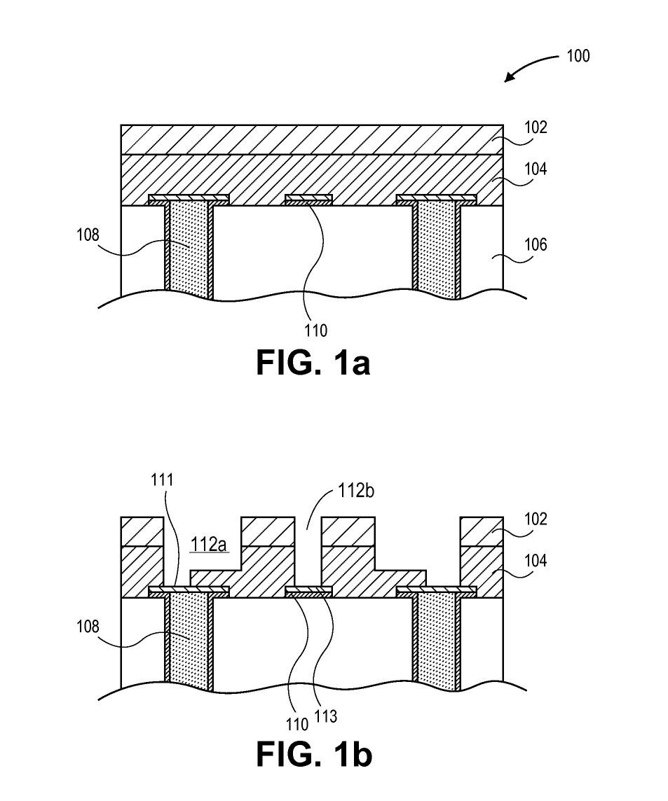

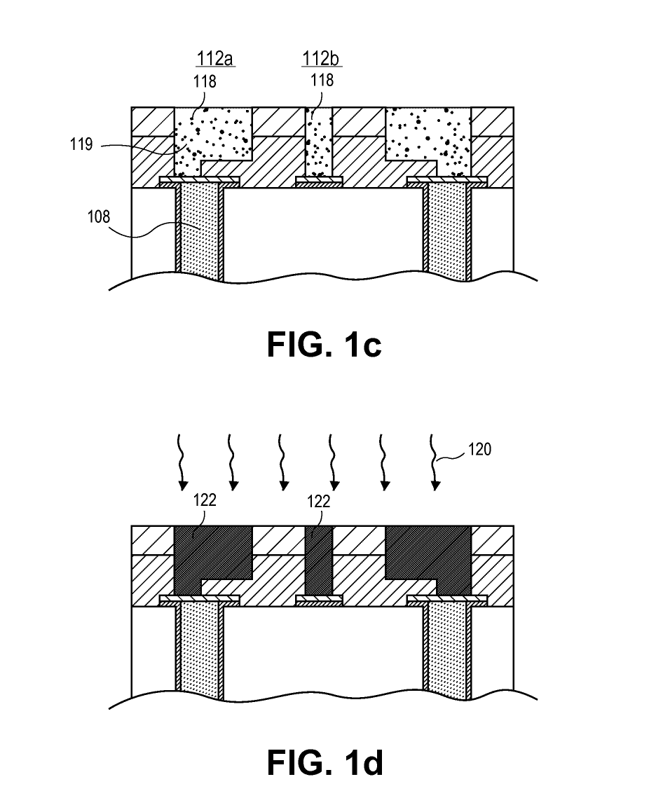

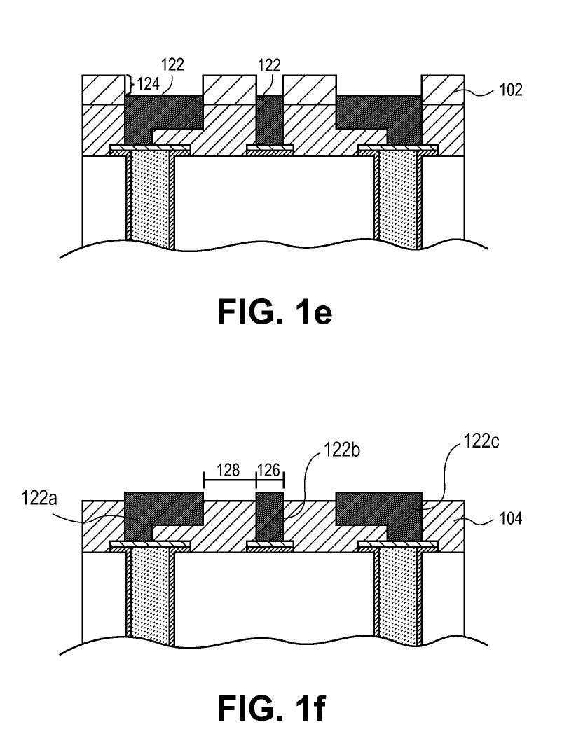

FIGS. 1a-1h illustrate embodiments of methods of forming microelectronic structures, such as methods for forming portions a package substrate, for example. FIG. 1a illustrates a cross-section of a portion of a package substrate 100 (the package substrate may comprise an organic substrate in an embodiment). The package substrate 100 may comprise a photosensitive material 102, such as a photoresist material, for example, a buildup material 104 (such as a polymer material), and core material 106. Other polymer materials instead of photo resist can be used as long as it can be selectively removed from the buildup material 104 by appropriate chemicals/processes. The package substrate 100 may further comprise at least one via structure 108 and at least one line structure 110, which may comprise conductive interconnect structures, such as conductive vias and conductive wiring within the package substrate 100 in some embodiments.

At least one opening 112a, 112b may be formed in/through the photosensitive material 102 and the build up material 104. In one embodiment, the at least one opening 112a may comprise via contact openings that may expose a contact 111 to the at least one via structure 108, and the at least one opening 112b may comprise a fine conductive line opening that may comprise a contact 113 to the at least one line structure 110. The at least one opening 112a, 112b may be formed by utilizing at least one of a laser ablation process and an imprinting process, such as a nano-imprinting process, in some embodiments.

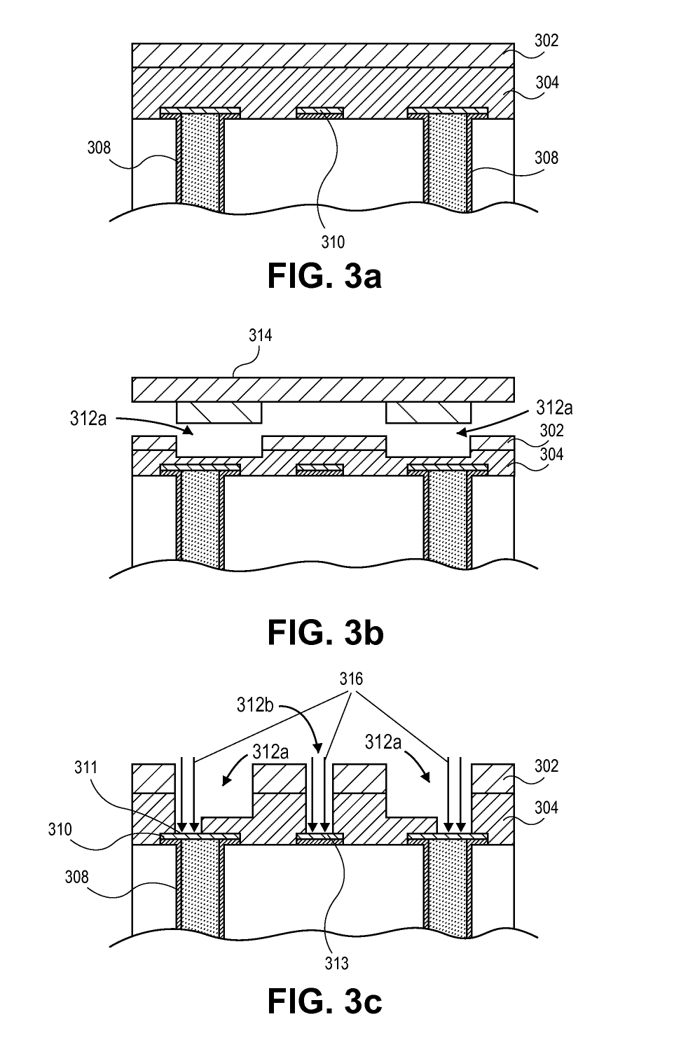

In one embodiment, a nano imprinting tool 314 may be used to form the at least one opening 312a through the photosensitive material 302 and a portion of the build up material 304 (FIGS. 3a-3b). The at least one opening 312b to the at least one line structure 310 may then be formed through both of the photosensitive material 302 and the build up material 304 by utilizing a laser ablation process 316, wherein the contact 313 to the at least one line structure 310 may be exposed (FIG. 3c). During the laser ablation process 316 that forms the at least one opening 312b, the at least one openings 312a may be completed/formed as well, by removing the remaining portions of the buildup material 304 to expose the contact 311 to the at least one via structure 308.

The thickness of photosensitive material 302 and/or build up material 304 may be varied, according to the particular application. For example, if it is difficult to make an imprint through the photosensitive material 302 and the buildup material 304 at a same time, the nano imprinting may be performed only on the photosensitive material 302 followed by the laser ablation of the buildup material 304.

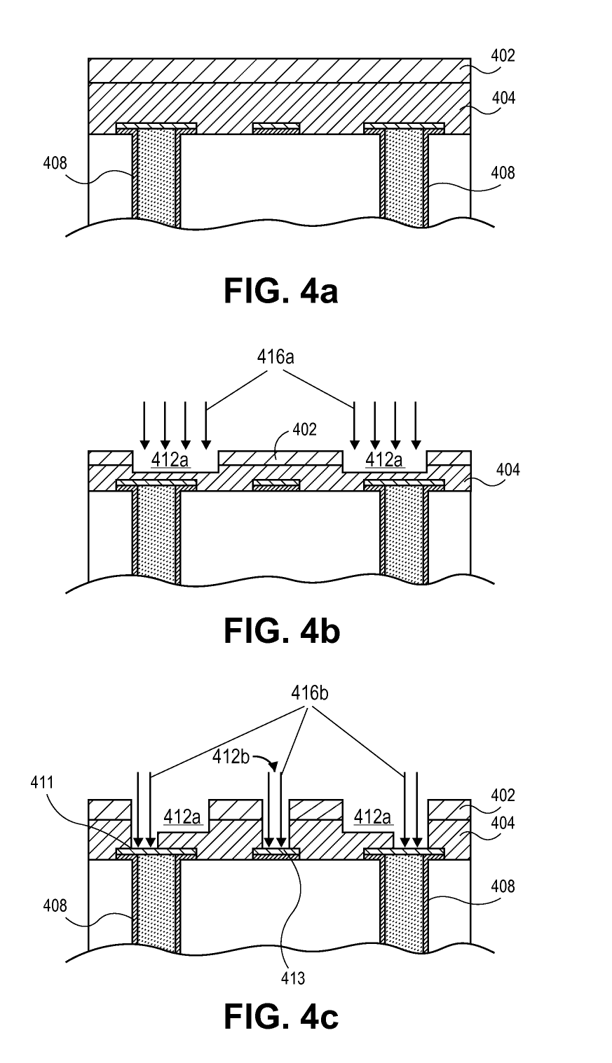

In another embodiment, a first laser ablation process 416a may be used to form a portion of the at least one opening 412a through the photosensitive material 402 and a portion of the build up material 404 (FIGS. 4a-4b). The at least one opening 412b may then be formed through both of the photosensitive material 402 and the build up material 404 by utilizing a second laser ablation process 416b, wherein the contact 413 to the at least one line structure 410 may be exposed (FIG. 4c). During the second laser ablation process 416b that forms the at least one opening 412b, the at least one openings 412a may be completed/formed as well, by removing the remaining portions of the buildup material 404 to expose the contact 411 to the at least one via structure 408.

Subsequent to the formation of the at least one openings 112a, 112b (referring back to FIG. 1c) the at least one openings 112a, 112b may be filled with a metallic containing nanopaste 118. In one embodiment, the at least one opening 112a, 112b may be filled with the metallic containing nanopaste 118 by utilizing a squeezing technique/and or a screen printing technique. The metallic containing nanopaste 118 may comprise metal nanopastes that may comprise nano-sized metal particles in some embodiments.

In one embodiment, the metallic containing nanopaste 118 may comprise at least one of silver, gold, tin and copper nano particles. In some embodiments, any type of metallic containing nanopaste can be used to fill the at least one opening 112a, 112b, that may comprise the capability of producing the nano-sized particles. For example, carbon nanotubes (CNT's) and metal nanopaste mixture pastes can also be used to produce metal and CNT composite structures, such as wire structures for example, with improved electrical and mechanical properties after a subsequent sintering process is performed, to be described herein.

In one embodiment, the metal nanoparticles may be covered with dispersants, reaction rate control agents, and some additives, such as solvents for example, to control viscosity. The solvents may be dispensed utilizing methods such as stencil printing and/or ink jet printing in some embodiments. In one embodiment, the dispersants may comprise alkanoic acid or amine compounds, and may be used for the reduction of the surface tension energy of the nano metal particles. In some embodiments, the reaction rate control agents may be stable at room temperature and experience no activation, and may comprise amine compounds, for example.

In one embodiment, the nano-sized metal particles of the metallic containing nanopaste 118 may comprise a metal that may undergo a subsequent sintering process. In one embodiment, the nano-sized metal particles may be covered with the dispersants so that they comprise a fine distribution without substantial agglomeration within the metal containing nanopaste 118. In one embodiment, the metallic containing nanopaste 118 may comprise copper nano particles that may comprise a mean diameter of about 5 nm. The diameter of the nano-sized metal particles may vary depending upon the particular application, but in some embodiments may comprise about 10 nm or less.

The metal containing nanopaste 118 may be exposed to a sintering process 120. The particular sintering process conditions 120, such as the sintering temperature and time conditions for example, may be controlled depending on the particular type of nanopaste materials. In one embodiment, at elevated temperatures, but lower than a sintering temperature, the reaction rate control agents may become activated by the raised temperature, and may begin to react with the dispersants in the metal containing nanopaste 118 and may remove the dispersants from the nano metal particles.

This may result in the nano metal particles agglomerating with each other, and inter-diffusion growth may occur as well between the nano metal particles to reduce their surface tension energies. As the temperature increases to the sintering temperature, the nano sized metal particles may be converted from nano sized particles 119 to form a bulk property metal structure 122 (FIG. 1d, depicting a portion of the unconverted metal containing nanopaste (a) and the converted metal containing nanopaste (b) after undergoing the sintering process 120). In one embodiment, the sintering temperature of the metal containing nanopaste may comprise a lower temperature than a melting temperature of the bulk property metal structure. In an embodiment, the bulk property metal structure 122 comprises little to no organic material and little to no nano sized metal particles.

Thus, the organic based material (dispersant, reaction control rate agents, additives) in the metallic containing nanopaste 118 may be removed during the sintering process 120 to form the bulk property metal structure 122. For the effective removal of the organic based material, various sintering processes may be utilized. In one embodiment, an air induced sintering process may be employed wherein a sintering temperature of between about 100 degrees Celsius to about 280 degrees Celsius may be applied to sinter a silver and/or gold containing nanopaste 118.

Oxygen present in air may diffuse into the nanopaste 118, and may easily react with organics to be vaporized, thereby forming the bulk property metal structures 122. In the cases of copper and/or tin nanopastes, oxidation of the metal nano particles may be controlled. In an embodiment, reducing environmental conditions (e.g., Ar-5% H2 mixture gas, N2-methanoic acid vapor mixture gas, etc.) can be used. Environmental pressure can also be one of the key sintering factors to control, as well as controlling the sintering process time and temperature to enhance the sintering quality. In one embodiment, the sintering time may comprise about 60 minutes or less.

In one embodiment, a volume change 124 may occur when the metal containing nanopaste 118 converts to the bulk property metal structure 122 (FIG. 1e). In some embodiments, the bulk property metal structure 122 may undergo a decrease in volume upon conversion. The photosensitive material 102 may be removed form the buildup material 104 (FIG. 1f), and additional buildup material 104a may be formed on the buildup material 104 to form a packaging structure 123, according to the particular application (FIG. 1g).

In one embodiment, the bulk property metal structure 122 may comprise a conductive structure, such as conductive wires in a microelectronic packaging application, for example (FIG. 1h). In one embodiment, adjacent bulk property metal structures 122a, 122b, 122c may comprise a line width 126 and a line spacing 128 between adjacent bulk property metal structures, such as between the bulk property metal structures 122a and 122b, for example. In one embodiment, the line width 126 may comprise about 10 microns or less, and the line spacing may comprise about 10 microns or less.

Thus, the ability to fabricate fine line/space metal wires of less than about 10/10 microns is enabled. The fabrication of metal wires with high aspect ratios is enabled as well. In conventional build up processes for high density package substrates and/or mother boards, fine line/space conductive wiring less of less than about 10/10 microns faces a critical challenge because of the difficulty in uniform direct fabrication of plated metals (especially copper) by chemical etching methods due to the side etching defects during wire patterning. The various embodiments of the present invention allows for the fabrication of metal wires for fine line/space applications, such as in high density package substrate or mother board fabrication, based on damascene techniques using metal containing nanopastes, without the need for chemical mechanical polishing (CMP) and direct pattern etching of deposited metals.

In another embodiment, a substrate 200 (similar to the substrate 100 in FIG. 1c, for example) may comprise a photosensitive material 202, a buildup material 204 and a metal containing paste 218. Prior to filling openings in the substrate 200 that may provide connections to conductive structures in the substrate 200, (such as but not limited to via structures and line structures) a hydrophobic material 209 may be applied to a top surface of the photosensitive material 202. The hydrophobic material 209 may prohibit the metal containing nanopaste 218 from remaining on the surface of the photosensitive material 202 after the metal containing nanopaste 218 is filled into openings (not shown), such as the at least one opening 112 of FIG. 1b, for example.

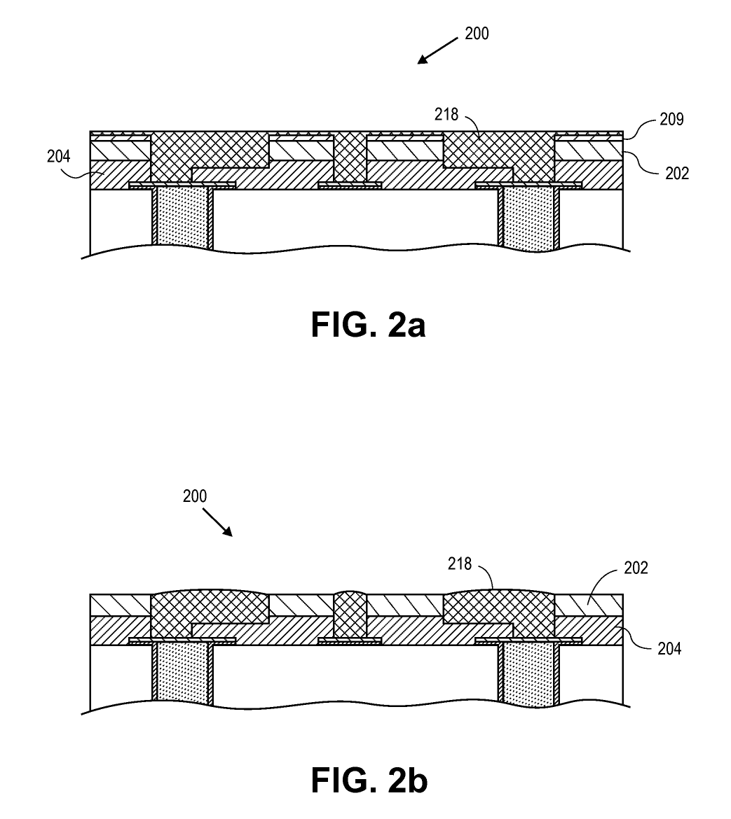

In one embodiment, the metal containing nanopaste 218 may remain on a top surface of the photosensitive material 202 after it has been squeezed into an opening. The metal containing nanopaste 218 on the top surface of the photosensitive material 202 can then be easily removed (FIG. 2b), while the metal containing nanopaste 218 remains in filled openings, such as in line cavities and via holes, for example, and a reduction in surface tension occurs.

The embodiments of the present invention offer many advantages. Delivering fine line/space metal wires of less than about 10/10 microns, with the capability of achieving high aspect ratios is enabled. A simple process by using metal containing nanopaste, as compared to conventional build up processes is described. Significant quality improvement can be expected by using trench forming techniques, such as damascene techniques, which allow high aspect ratio of fabricated metal wires according to the embodiments of the present invention. Cost reduction can be realized by eliminating CMP steps during processing, as well as by eliminating the need for chemical etching, plating, seed sputtering, and electro plating processes.

FIG. 5 is a diagram illustrating a system 500 capable of being operated with methods for fabricating a microelectronic structure, such as the packaging structure 123 of FIG. 1g, for example. It will be understood that the present embodiment is but one of many possible systems in which the packaging structures of the present invention may be used.

In the system 500, the packaging structure 524 may be communicatively coupled to a printed circuit board (PCB) 518 by way of an I/O bus 508. The communicative coupling of the packaging structure 524 may be established by physical means, such as through the use of a package and/or a socket connection to mount the packaging structure 524 to the PCB 518 (for example by the use of a chip package, interposer and/or a land grid array socket). The packaging structure 524 may also be communicatively coupled to the PCB 518 through various wireless means (for example, without the use of a physical connection to the PCB), as are well known in the art.

The system 500 may include a computing device 502, such as a processor, and a cache memory 504 communicatively coupled to each other through a processor bus 505. The processor bus 505 and the I/O bus 508 may be bridged by a host bridge 506. Communicatively coupled to the I/O bus 508 and also to the packaging structure 524 may be a main memory 512. Examples of the main memory 512 may include, but are not limited to, static random access memory (SRAM) and/or dynamic random access memory (DRAM), and/or some other state preserving mediums. The system 500 may also include a graphics coprocessor 513, however incorporation of the graphics coprocessor 513 into the system 500 is not necessary to the operation of the system 500. Coupled to the I/O bus 508 may also, for example, be a display device 514, a mass storage device 520, and keyboard and pointing devices 522.

These elements perform their conventional functions well known in the art. In particular, mass storage 520 may be used to provide long-term storage for the executable instructions for a method for forming packaging structures in accordance with embodiments of the present invention, whereas main memory 512 may be used to store on a shorter term basis the executable instructions of a method for forming packaging structures in accordance with embodiments of the present invention during execution by computing device 502. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 512 may supply the computing device 502 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic packaging structures are well known in the art. Therefore, it is appreciated that the Figures provided herein illustrate only portions of an exemplary microelectronic packaging structure that pertains to the practice of the present invention. Thus the present invention is not limited to the structures described herein.

1. A method comprising:
forming at least one opening through a build up structure and a photosensitive material disposed on the build up structure, wherein the build up structure comprises a portion of a package substrate wherein forming said at least one opening includes forming a line portion through said photosensitive material and into said buildup structure with a first opening process and forming a via contact portion in said build up structure with a second opening process, wherein the line portion is entirely formed with a single patterning operation, wherein said line portion is wider than said via contact portion;
applying a hydrophobic material to a top surface of the photosensitive material;
filling the line portion in said photosensitive material and the via contact portion in said build up structure with a metal containing nanopaste, wherein the metal containing nanopaste comprises metal nanoparticles, dispersants, reaction rate control agents, and additives; and
sintering the metal containing nanopaste without the application of external pressure to form a bulk property metal structure in the at least one opening, wherein a sintering temperature is less than about 280 degrees Celsius, and wherein sintering the metal containing nanopaste substantially removes the dispersants, reaction rate control agents, and additives from the metal containing nanopaste.

2-3. (canceled)

4. The method of claim 1 further comprising wherein the single patterning operation of the first opening process is nano imprinting or laser ablation.

5. The method of claim 1 wherein the bulk property metal structure comprises at least one of a metal contact via structure and a metal wire structure.

6. The method of claim 1 further comprising wherein the sintering temperature is held for less than about 60 minutes.

7. A method comprising:
forming at least one opening through a photosensitive material and a build up structure, wherein the photosensitive material is disposed on the build up structure, and wherein the build up structure comprises a portion of a package substrate, wherein forming said at least one opening includes forming a line portion through said photosensitive material and into said buildup structure with a first opening process and forming a via contact portion in said build up structure with a second opening process, wherein the line portion is entirely formed with a single patterning operation, wherein said line portion is wider than said via contact portion and wherein the at least one opening comprises a width of less than about 10 microns and a space of less than about 10 microns between adjacent openings;
applying a hydrophobic material to a top surface of the photosensitive material;
filling the line portion in said photosensitive material and the via contact portion in said build up structure with a metal containing nanopaste, wherein the metal containing nanopaste comprises metal nanoparticles, dispersants, reaction rate control agents, and additives; and
sintering the metal containing nanopaste without the application of external pressure to form a bulk property metal structure in the at least one opening, wherein a sintering temperature is less than about 280 degrees Celsius, and wherein sintering the metal containing nanopaste substantially removes the dispersants, reaction rate control agents, and additives from the metal containing nanopaste.

8. The method of claim 7 further comprising wherein the package substrate comprises at least one of a high density package substrate and a motherboard.

9. (canceled)

10. The method of claim 7 further comprising wherein the metal containing nanopaste comprises copper nanoparticles comprising a diameter of about 6 nm or less, and wherein the dispersants comprise at least one of alkanoic acid and amine compounds, and wherein the reaction rate control agents comprise an amine compound, and wherein the additives comprise solvents.

11. The method of claim 7 further comprising wherein the sintering temperature is held for about 60 minutes or less.

12. The method of claim 11 further comprising wherein the sintering temperature of the metal containing nanopaste comprises a lower temperature than a melting temperature of the bulk property metal structure.

13. (canceled)

14. The method of claim 7 further comprising wherein filling the at least one opening with a metal containing nanopaste comprises at least one of squeezing and screen printing.

15. (canceled)

16. The method of claim 7 further comprising wherein the second opening process includes laser ablation.

17. The method of claim 7 further comprising wherein the bulk property metal structure comprises a metal wire structure with a line width of about 10 microns or less and a line spacing of about 10 microns or less.

18-25. (canceled)

26. The method of claim 7, wherein sintering the metal containing nanopaste comprises:
raising the temperature of the metal containing nanopaste to a temperature sufficient to activate the reaction rate control agents and lower than the sintering temperature, wherein the activated reaction rate control agents react with the dispersants in the metal containing nanopaste and cause the dispersants to be removed from the metal containing nanopaste.
